(19) United States
(12) Patent Application Publication
(10) Pub. No.: US 2005/0285162 A1
(43) Pub. Date: Dec. 29, 2005

(54) Semiconductor devices having a stacked structure and methods of forming the same

(76) Inventors: Chul-Sung Kim, Gyeonggi-do (KR); Jin-Hwa Heo, Gyeonggi-do (KR); Yu-Gyun Shin, Gyeonggi-do (KR); Bon-Young Koo, Gyeonggi-do (KR); Dong-Chan Kim, Gyeonggi-do (KR); Jeong-Do Ryu, Seoul (KR)

Correspondence Address: Robert W. Glatz;Myers Bigel Sibley & Sajovec, Post Office Box 37428, Raleigh, NC, 27627, US

(21) Appl. No.: 11/159,596

(22) Filed: Jun. 23, 2005

(30) Foreign Application Priority Data
Jun. 25, 2004 (KR) 10-2004-48150

(51) Int. Cl. H01L 29/78; H01L 21/8234; H01L 21/8244

(52) U.S. Cl. 257/288; 438/197; 438/455; 257/366

(57) ABSTRACT

Methods of forming a semiconductor device having stacked structures include forming a first semiconductor structure on a substrate and forming a first interlayer insulating layer on the substrate. The first interlayer insulating layer has a substantially level upper face. A semiconductor layer is formed on the first interlayer insulating layer and a first gate insulation layer is formed on the semiconductor layer at a processing temperature selected to control damage to the first semiconductor structure. A second semiconductor structure is formed on the first gate insulation layer.

### CROSS REFERENCE TO RELATED APPLICATION

This application is related to and claims priority under 35 U.S.C. § 119 from Korean Patent Application 2004-48150 filed on Jun. 25, 2004, the entire contents of which are hereby incorporated by reference.

### BACKGROUND OF THE INVENTION

The present invention relates to a semiconductor device including a stacked structure and a method of manufacturing the semiconductor device, and more particularly, to a semiconductor device including a vertically stacked structure and a method of manufacturing the semiconductor device.

For high integration density semiconductor (integrated circuit) devices, a plurality of structures are generally formed on a single semiconductor (integrated circuit) substrate. These structures of the semiconductor device may be integrated on the substrate by reducing their dimensions or by vertically stacking the structures on the substrate. For example, as a static random access memory (SRAM) device typically has a unit cell including six transistors, several transistors may be vertically stacked to improve the integration density of the SRAM device.

Examples of a conventional semiconductor device including vertically stacked structures are described in Japanese Patent Laid-Open Publication No. 2000-208644, Korean Patent Laid-Open Publication No. 2002-96743, and U.S. Pat. No. 5,670,390 issued to Muragishi.

In a conventional method of forming a conventional semiconductor device including vertically stacked structures, a lower semiconductor structure having a gate structure is generally formed on a substrate. An insulating interlayer is formed on the substrate to cover the lower semiconductor structure. After an additional substrate structure of silicon is formed on the insulating interlayer, an upper semiconductor structure is formed on the additional substrate. As a result, the semiconductor device has the vertically stacked lower and upper semiconductor structures. However, the semiconductor structures are typically formed via several high temperature processes, such as oxidation processes for forming gate oxide layers on the substrates and for oxidizing sidewalls of gate electrodes to cure damage to the gate electrodes and to improve gate induced drain leakage (GIDL) characteristics of the gate electrodes. When the semiconductor structures are formed at a high temperature of above about 850° C. for a relatively long time, the semiconductor structures, particularly the lower semiconductor structures, may be seriously thermally damaged. This damage may deteriorate electrical characteristics of the semiconductor device.

### SUMMARY OF THE INVENTION

Embodiments of the present invention provide methods of forming a semiconductor device having stacked structures including forming a first semiconductor structure on a substrate and forming a First interlayer insulating layer on the substrate. The first interlayer insulating layer has a substantially level upper face. A semiconductor layer is formed on the first interlayer insulating layer and a first gate insulation layer is formed on the semiconductor layer at a processing temperature selected to control a damage to the first semiconductor structure. A second semiconductor structure is formed on the first gate insulation layer.

In other embodiments of the present invention, forming a first gate insulation layer on the semiconductor layer at a processing temperature selected to control the damage to the first semiconductor structure includes forming the first gate insulation layer at a temperature of about 25 to about 800° C. The first gate insulation layer may be formed using a plasma oxidation process. The method may further include nitrifying the first gate insulation layer at a temperature of below about 500° C. The first gate insulation layer may be nitrified using a plasma nitrification process.

In further embodiments of the present invention, the first semiconductor structure includes a first gate structure including a first gate conductive pattern and the second semiconductor structure includes a second gate structure including a second gate conductive pattern and the semiconductor layer includes silicon. A first sidewall layer may be formed on a sidewall of the first gate conductive pattern and a first gate spacer may be formed on the first sidewall layer. A second sidewall layer may be formed on the second gate conductive pattern and a second gate spacer may be formed on the second sidewall layer. The second sidewall layer may be formed by an oxidation process at a temperature of about 25 to about 800° C.

In other embodiments of the present invention, the methods further include successively forming interlayer insulating layers, semiconductor layers, gate insulation layers and semiconductor structures on the semiconductor device to provide a semiconductor device having at least three vertically stacked semiconductor structures formed at a processing temperature selected to control damage to underlying semiconductor structures while forming the successive gate insulation layers. The device may be a static random access memory (SRAM) having six transistors and successively forming may include successively forming six vertically stacked semiconductor structures to form the six transistors.

In other embodiments of the present invention, source/drain regions are formed in the substrate proximate the first semiconductor structure. Source/drain regions are also formed in the semiconductor layer proximate the second semiconductor structure.

In some embodiments of the present invention, semiconductor devices are provided formed according to methods as described above. The device may be a static random access memory (SRAM) having six transistors that includes six vertically stacked semiconductor structures that provide the six transistors.

In yet further embodiments of the present invention, methods of manufacturing a semiconductor device having stacked structures include forming a first semiconductor structure on a first substrate, the first semiconductor structure including a first gate structure that has a first gate conductive pattern. A first interlayer insulating layer is formed on the first substrate, the first interlayer insulating layer having a level upper face. A second substrate is formed on the first interlayer insulating layer, the second substrate including silicon. A first gate insulation layer is formed on the second substrate without damaging the first semiconductor structure. A second semiconductor structure is formed on the first gate insulation layer, the second semiconductor structure including a second gate structure that has a second gate conductive pattern.

The first gate insulation layer may be formed at a temperature of about 25 to about 800° C. The first gate insulation layer may be formed by a plasma oxidation process. The methods may further include nitrifying the first gate insulation layer at a temperature of below about 500° C. and the first gate insulation layer may be nitrified by a plasma nitrification process.

In other embodiments, the methods further include forming a second to a Kth (K is an integer greater than 2) interlayer insulating layers formed on the first gate insulation layer. A third to an Lth (L is an integer greater than 3) substrates formed on the second to the Kth interlayer insulating layers, respectively are formed. A third to an Mth (M is an integer greater than 3) gate insulation layers formed on the third to the Lth substrates, respectively are formed and a third to an Nth (N is an integer greater than 3) semiconductor structures formed on the third to the Mth gate insulation layers, respectively are formed.

In accordance with one aspect of the present invention, there is provided a semiconductor device having stacked structures. The semiconductor device includes a first semiconductor structure formed on a first substrate, a first insulating interlayer formed on the first substrate, a second substrate formed on the first insulating interlayer, a first gate insulation layer formed on the second substrate, and a second semiconductor structure formed on the first gate insulation layer. The first semiconductor structure may include a first gate structure that has a first gate conductive pattern. The first insulating interlayer may have a level upper face. The second substrate may include single crystalline silicon or polycrystalline silicon. The first gate insulation layer may be formed through a process without the damage to the first semiconductor structure. The second semiconductor structure may include a second gate structure that has a second gate conductive pattern.

In some embodiments of the present invention, the first gate insulation layer includes an oxide film formed by a plasma oxidation process at a temperature of about 25 to about 800° C. In some embodiments of the present invention, the first gate insulation layer includes an oxynitride film formed by nitrifying an oxide film using a plasma nitrification process at a temperature of below about 500° C. after the oxide film is formed on the second substrate by a plasma oxidation process at a temperature of about 25 to about 800° C.

In further embodiments of the present invention, the semiconductor device further includes a second gate insulation layer formed between on the first substrate and the first semiconductor structure. The first semiconductor structure may further include a first sidewall layer formed on a sidewall of the first gate conductive pattern. The first semiconductor structure may further include a first gate spacer formed on the first sidewall layer.

In other embodiments of the present invention, the second semiconductor structure further includes a second sidewall layer formed on a sidewall of the second gate conductive pattern. Here, the second sidewall layer is formed by a plasma oxidation process at a temperature of about 25 to about 800° C. to cure an etch damage to the second gate conductive pattern. The second semiconductor structure may further include a second gate spacer formed on the second sidewall layer.

In further embodiments of the present invention, the semiconductor device further includes a second to a Kth (K is an integer greater than 2) insulating interlayers formed on the first gate insulation layer, a third to an Lth (L is an integer greater than 3) substrates formed on the second to the Kth insulating interlayers, respectively, a third to an Mth (M is an integer greater than 3) gate insulation layers formed on the third to the Lth substrates, respectively, and a third to an Nth (N is an integer greater than 3) semiconductor structures formed on the third to the Mth gate insulation layers, respectively.

### BRIEF DESCRIPTION OF THE DRAWINGS

Embodiments of the present invention will now be further described with reference to the figures.

FIG. 1 is a cross sectional view illustrating a semiconductor device having stacked structures in accordance with some embodiments of the present invention.

FIGS. 2A to 2I are cross sectional views illustrating methods of manufacturing a semiconductor device including stacked structures in accordance with some embodiments of the present invention.

FIG. 3 is a cross sectional view illustrating methods of manufacturing a semiconductor device having stacked structures in accordance with some embodiments of the present invention.

FIG. 4 is a cross sectional view illustrating methods of manufacturing a semiconductor device having stacked structures in accordance with some embodiments of the present invention.

### DETAILED DESCRIPTION OF EMBODIMENTS OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

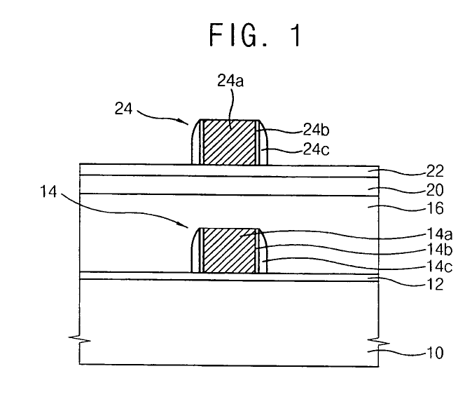

Referring now to the embodiments of FIG. 1, the illustrated semiconductor device includes a first semiconductor structure 14 formed on a first semiconductor substrate 10 and a second semiconductor structure 24 formed on a second semiconductor layer 20. An interlayer insulating layer 16 is formed between the substrate 10 and the semiconductor layer 20. The interlayer insulating layer 16 is formed on the substrate 10 to completely cover the first semiconductor structure 14.

The substrate 10 may be a silicon wafer, a silicon-on-insulator (SOI) substrate, a single crystalline silicon substrate, a polycrystalline silicon substrate or the like. The first semiconductor structure 14 may include a first gate structure, source/drain regions, a metal wiring, a pad, a plug, a transistor, a capacitor and the like. As shown in the embodiments of FIG. 1, the first gate structure 14 includes a first gate insulation layer 12 and a first gate conductive pattern 14a.

The first gate insulation layer 12 may include an oxide such as silicon oxide, and the first gate conductive pattern 14a may include polysilicon. In other embodiments, the first gate conductive pattern 14a may be formed using a conductive material, such as a metal or a metal nitride.

The first gate conductive pattern 14a may be formed on the first gate insulation layer 12 from a first gate conductive layer that is first formed on the first gate insulation layer 12. The first gate conductive layer may be patterned to form the first gate conductive pattern 14a through, for example, a photolithography process.

The first gate insulation layer 12, in some embodiments of the present invention, may be partially etched using a photolithography process to form a first gate insulation layer pattern on the first substrate 10 (in other words, the layer 12 may not extend across the substrate 10 as illustrated in FIG. 1 but may be patterned to be present only under the gate structure 14).

The first gate structure in the embodiments of FIG. 1 further includes a first sidewall layer 14b and a first gate spacer 14c. The first sidewall layer 14b is on a sidewall of the first gate conductive pattern 14a, and the first gate spacer 14c is positioned on the first sidewall layer 14b.

The first sidewall layer 14b may be included to compensate for damage to the first gate conductive pattern 14a generated during an etching process used when forming the first gate conductive pattern 14a. The first sidewall layer 14b may include oxide and the first sidewall layer 14a may then be referred to as a first sidewall oxide layer.

The first gate spacer 14c may include a material that has an etching selectivity relative to the first sidewall layer 14b and the insulating interlayer 16. For example, the first gate spacer 14c may be formed of a nitride, such as silicon nitride.

The interlayer insulating layer 16 is shown positioned on the substrate 10 to cover the first semiconductor structure 14, including the first gate structure. The interlayer insulating layer 16 serves as an isolation layer that electrically isolates the first semiconductor structure 14 from the second semiconductor structure 24. The interlayer insulating layer 16 may include an oxide or a nitride. The interlayer insulating layer 16 in the embodiments of FIG. 1 has a level upper surface and the semiconductor layer 20 is placed on the level upper surface of the interlayer insulating layer 16. For example, an upper portion of the insulating interlayer 16 may be planarized by a planarization process, such as a chemical mechanical polishing (CMP) process, an etch back process or a combination process of CMP and etch back, before forming the semiconductor layer 20 on the planarized interlayer insulating layer 16. The semiconductor layer 20 may include single crystalline silicon and/or polycrystalline silicon because a single crystalline silicon layer and/or a poly crystalline silicon layer typically may be readily formed on interlayer insulating layer 16. For example, the semiconductor layer 20 may be a thin single crystalline silicon layer and/or a thin polycrystalline silicon layer. The semiconductor layer 20 may also be referred to herein as a “second substrate.”

The second semiconductor structure 24 is formed on the semiconductor layer 20. The second semiconductor structure 24 may include a second gate structure, source/drain regions, a pad, a plug, a metal wiring, a transistor, a capacitor and the like. As shown in the embodiments of FIG. 1, the second gate structure includes a second gate insulation layer 22 and a second gate conductive pattern 24a.

When the second gate insulation layer 22 is formed at a temperature of more than about 500° C., the first semiconductor structure 14 may be thermally damaged during formation of the second gate insulation layer 22. Thus, the second gate insulation layer 22 in some embodiments of the present invention is formed at a selected temperature that is selected to control thermal damage to the first semiconductor structure 14. For example, the second gate insulation layer 22 in some embodiments is formed using a plasma oxidation process at a temperature of less than about 500° C. The second gate insulation layer 22 may include an oxide film formed by a plasma oxidation process at a temperature of about 200 to about 450° C. In particular embodiments, the second gate insulation layer 22 includes an oxide film formed by a plasma oxidation process at a temperature of about 300 to about 450° C.

When the second semiconductor structure 24 includes a P type metal oxide semiconductor (MOS) transistor, an oxide film may be formed on the semiconductor layer 20 and then the oxide film may be nitrified to form the second gate insulation layer 22. This nitrified second gate insulation layer 22 may effectively prevent impurities, such as boron, from penetrating into the second gate structure and the semiconductor layer 20. When the oxide film is nitrified at a temperature of more than about 500° C., the first semiconductor structure 14 may also be thermally damaged during the nitrification process of the oxide film. Hence, the nitrification process in some embodiments of the present invention is performed at a selected temperature to control/limit thermal damage to the first semiconductor structure 14. For example, the oxide film in some embodiments is nitrified using a plasma nitrification process at a temperature of less than about 500° C. The oxide film in particular embodiments is nitrified by a plasma oxidation process at a temperature of about 100 to about 450° C. In further embodiments, the oxide film is nitrified by a plasma oxidation process at a temperature of about 200 to about 450° C. In yet other embodiments, the oxide film is nitrified by a plasma oxidation process at a temperature of about 300 to about 450° C. After the oxide film is nitrified as described above, the second gate insulation layer 22, including an oxynitride film, is formed on the semiconductor layer 20.

The second gate conductive pattern 24a may include a conductive material, such as polysilicon doped with impurities. In other embodiments, the second gate conductive pattern 24a may be formed using metal or metal nitride. After a second gate conductive layer is formed on the second gate insulation layer 22, the second gate conductive layer may be patterned by a photolithography process to form the second gate conductive pattern 24a on the second gate insulation layer 22. In some embodiments of the present invention, the second gate insulation layer 22 may be patterned to form a second gate insulation layer pattern on the second substrate 20 (in other words, the layer 22 may not extend across the entire section in FIG. 1 but may be provided just under the gate structure of the semiconductor structure 24 or the like).

The second gate structure in the illustrated embodiments also includes a second sidewall layer 24b and a second gate spacer 24c. The second sidewall layer 24b is shown formed on a sidewall of the second gate conductive pattern 24a and the second gate spacer 24c is shown formed on the second sidewall layer 24b.

The second sidewall layer 24b may be provided to compensate for damage to the second gate conductive pattern 24a generated during an etching process used when forming the second gate conductive pattern 24a. Thus, the second sidewall layer 24b may be formed using oxide. When the second sidewall layer 24b including an oxide film is formed at a temperature of more than about 500° C., the first and second semiconductor structures 14 and 24 may be thermally damaged during formation of the second sidewall layer 24b. Therefore, the second sidewall layer 24b may be formed at a selected or predetermined temperature that is selected to control damage to the first and second semiconductor structures 14 and 24. For example, the second sidewall layer 24b may be formed using a plasma oxidation process at a temperature of less than about 500° C. In some embodiments, the second sidewall layer 24b is formed by a plasma oxidation process at a temperature of about 100 to about 450° C. In particular embodiments, the second sidewall layer 24b includes an oxide film formed by a plasma oxidation process at a temperature of about 200 to about 450° C. In further embodiments, the second sidewall layer 24b is formed by a plasma oxidation process at a temperature of about 300 to about 450° C. The second sidewall layer 24b including the oxide film may be referred to as a second sidewall oxide layer.

In some embodiments of the present invention, a second interlayer insulating layer (and so on through a Kth interlayer insulating layer (K being an integer equal to or greater than 3)) may be successively formed and built up on the semiconductor layer 20. It will be understood that for the third layer, a third semiconductor layer (which may be referred to as a third substrate) and so on for subsequent layers through an Lth (L being an integer equal to or greater than 4) semiconductor layer may be formed between respective ones of the interlayer insulating layers. For example, a second interlayer insulating layer is formed on the semiconductor substrate 20, and then a third substrate (semiconductor layer) is positioned on the second interlayer insulating layer. In addition, a third interlayer insulating layer may be formed on the third substrate, and then a fourth substrate is placed on the third interlayer insulating layer. In this manner, the Lth substrate may be formed on the K-th interlayer insulating layer. Similarly, it will be understood that a third gate insulation layer through an Mth (M being an integer equal to or greater than 4) gate insulation layer may be formed on the third substrate to the Lth substrate, respectively. Moreover, a third semiconductor structure to an Nth semiconductor structure (N being an integer equal to or greater than 4) semiconductor structure may be formed on the third gate insulation layer to the Mth gate insulation layer, respectively. The third to the M-th semiconductor structures may be substantially identical to the first and/or the second semiconductor structure.

According some embodiments of the present invention, a semiconductor device has vertically stacked semiconductor structures without thermal or other damage to underlying semiconductor structures, which damage control may be provided by controlling processing conditions in processes of forming subsequent semiconductor structures. Thus, the semiconductor structures may have good characteristics even when a plurality of semiconductor structures is vertically stacked.

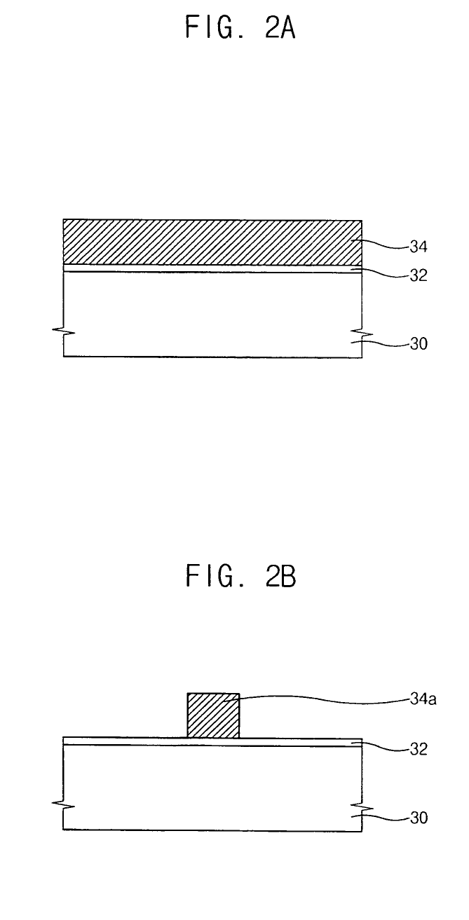

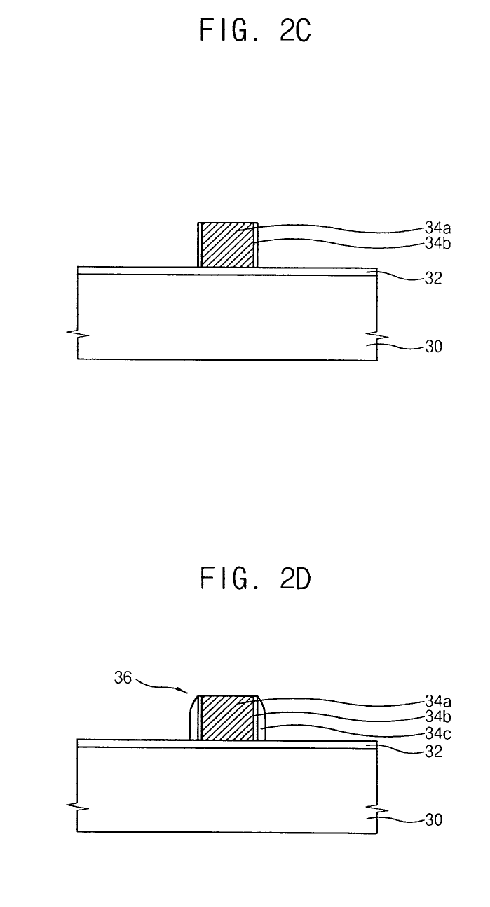

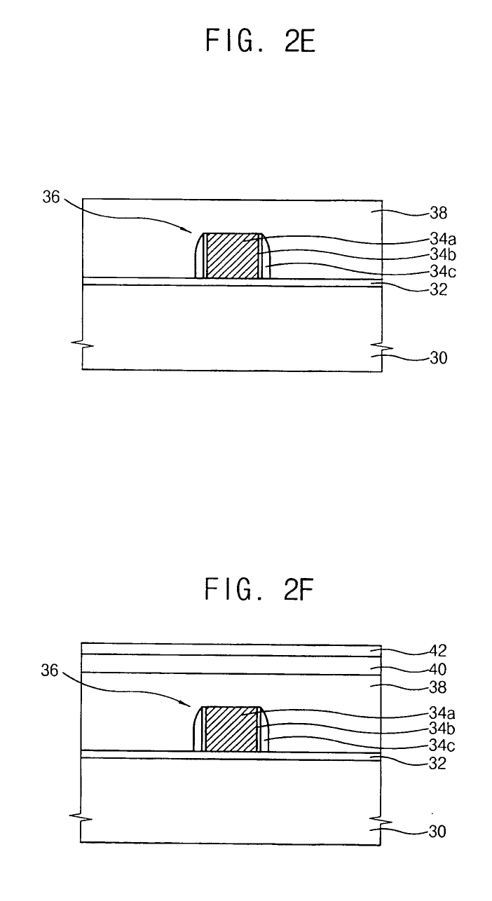

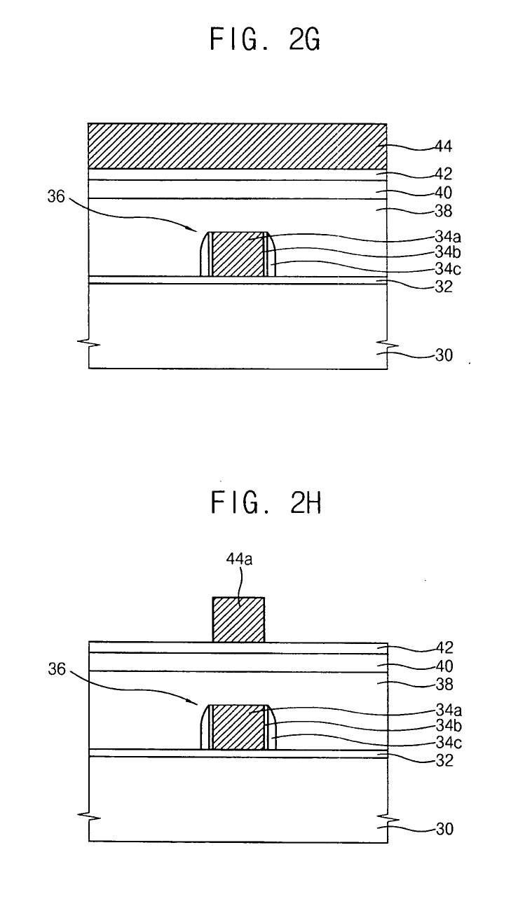

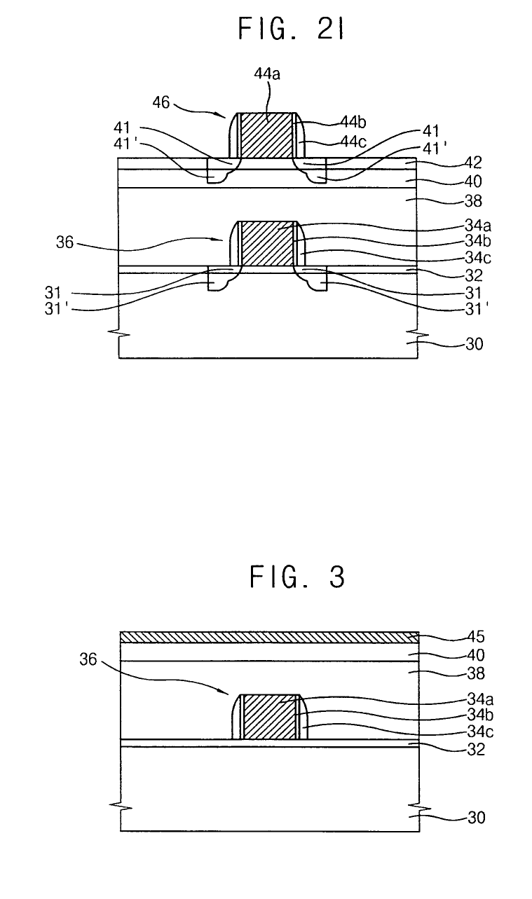

FIGS. 2A to 2I are cross sectional views illustrating methods of manufacturing a semiconductor device including stacked structures in accordance some embodiments of the present invention. Referring first to FIG. 2A, a first gate oxide layer 32 is formed on a first substrate 30. The first substrate 30 may include a silicon wafer, an SOI substrate, a single crystalline silicon substrate, a polycrystalline silicon substrate or the like. The first gate oxide layer 32 may be formed by a thermal oxidation process and/or a chemical vapor deposition (CVD) process.

A first gate conductive layer 34 is formed on the first gate oxide layer 32 using a conductive material. For example, the first gate conductive layer 34 may be formed using polysilicon by a CVD process.

As shown in FIG. 2B, the first gate conductive layer 34 is patterned, for example, by a photolithography process, to form a first gate conductive pattern 34a on the first gate oxide layer 32. In particular embodiments, a photoresist film is formed on the first gate conductive layer 34, and then the photoresist film is exposed and developed to form a photoresist pattern on the first gate conductive layer 34. The first gate conductive layer 34 is partially etched using the photoresist pattern as an etching mask so that the first gate conductive pattern 34a is formed on the first gate oxide layer 32. Then, the photoresist pattern is removed from the first gate conductive pattern 34a by, for example, an ashing process and/or a stripping process.

In some embodiments of the present invention, the first gate oxide layer 32 may be patterned to form a first gate oxide layer pattern between the first substrate 30 and the first gate conductive pattern 34a. In such embodiments, the first gate oxide layer 32 may be partially etched using the photoresist pattern as an etching mask. In other embodiments of the present invention, an anti-reflective layer (ARL) may be formed on the photoresist film to ensure the process margin of the photolithography process for forming the first gate conductive pattern 34a.

Referring now to FIG. 2C, as a sidewall of the first gate conductive pattern 34a may be damaged during the above-described etching process, a first sidewall oxide layer 34b is shown formed on the sidewall of the first gate conductive pattern 34a to address damage to the first gate conductive pattern 34a. The first sidewall oxide layer 34b may be formed by thermally oxidizing the sidewall of the first gate conductive pattern 34a.

Referring now to FIG. 2D, a first insulation layer is formed on the first gate oxide layer 32 to cover the first gate conductive pattern 34a. The first insulation layer may be formed using a nitride, such as silicon nitride. The first insulation layer in other embodiments may include an oxynitride, such as silicon oxynitride. The first insulation layer in the illustrated embodiments of FIG. 2D is partially etched to form a first gate spacer 34c on the first sidewall oxide layer 34b. For example, the first insulation layer may be anisotropically etched to form the first gate spacer 34c. As a result, a first gate structure 36 including the first gate oxide layer 32, the first gate conductive pattern 34a, the first sidewall oxide layer 34b and the first gate spacer 34c may be formed on the first substrate 30.

Before the first gate spacer 34c is formed on the first sidewall oxide layer 34b, impurities may be implanted into portions of the first substrate 30 adjacent to the first gate conductive pattern 34a by, for example, an ion implantation process, to form first source/drain regions in these portions of the first substrate 30.

In some embodiments of the present invention shown in FIG. 2I, impurities may be implanted into portions of the first substrate 30 adjacent to the first gate conductive pattern 34a to form first preliminary source/drain regions 31 at these portions of the first substrate 30. Then, additional impurities may be implanted into the portions of the first substrate 30 where the first preliminary source/drain regions 31 are positioned to form first source/drain regions 31′ having lightly doped drain (LDD) structures. The first preliminary source/drain regions 31 may have relatively shallow junction depths, whereas the first source/drain regions 31′ may have relatively deep junction depths.

A first wiring structure (or first metal layer) may be formed over the first gate structure 36 using a conductive material, such as a metal, a metal nitride, doped polysilicon or the like. The first wiring structure may be electrically connected to the first gate structure 36. As such, a first semiconductor structure including the first gate structure 36 and the first wiring structure may be formed on the first substrate 30.

As shown in FIG. 2E, an interlayer insulating layer 38 is formed on the first substrate 30 to cover the first semiconductor structure. The interlayer insulating layer 38 electrically isolates lower conductive structures, such as the first gate structure 36 and the first wiring structure, from a second gate structure 46 (see FIG. 2I) subsequently formed. The interlayer insulating layer 38 may include an oxide, such as undoped silicate glass (USG), spin on glass (SOG), plasma enhanced tetraethylorthosilicate (PE-TEOS), high density plasma chemical vapor deposition (HDP-CVD) oxide and/or the like.

An upper portion of the insulating interlayer 38 is planarized (flattened) by a planarization process, such as CMP process, an etch back process or a combination process of CMP and etch back. As a result, the interlayer insulating layer 38 may be provided a level upper face.

Referring now to FIG. 2F, a single crystalline silicon layer or a polycrystalline silicon layer is formed on the insulating interlayer 38 as a semiconductor layer (second substrate) 40. A second gate oxide layer 42 is formed on the semiconductor layer 40. The second gate oxide layer 42 may be formed, for example,e using a plasma oxidation process and/or a CVP process.

When the second gate oxide layer 42 is formed by a plasma oxidation process, the second gate oxide layer 42 may be formed at a temperature of about 25 to about 800° C. In some embodiments, the second gate oxide layer 42 is formed at a temperature of below about 400° C. so that the underlying first semiconductor structure may not be thermally damaged in the formation of the second gate oxide layer 42.

As shown in FIG. 2G, a second gate conductive layer 44 is formed on the second gate oxide layer 42. The second gate conductive layer 44 may be formed by, for example, a CVD process using a conductive material, such as doped polysilicon, a metal, a metal nitride and/or the like.

Referring to FIG. 2H, the second gate conductive layer 42 is patterned by, for example, a photolithography process to form a second gate conductive pattern 44a on the second gate oxide layer 42. The second gate conductive pattern 42 may be formed by an etching process substantially identical to that of the first gate conductive pattern 34a.

In some embodiments of the present invention, the second gate oxide layer 42 may be partially etched to form a second gate oxide layer pattern between the second substrate 40 and the second gate conductive pattern 44a.

As shown in FIG. 2I, a second sidewall oxide layer 44b may be formed on a sidewall of the second gate conductive pattern 44a, which may cure damage to the second gate conductive pattern 44a due to the etching process used thereon. The second sidewall oxide layer 44b may be formed, for example, by oxidizing the sidewall of the second gate conductive pattern 44a. In particular embodiments, the second sidewall oxide layer 44b is formed on the sidewall of the second gate conductive pattern 44a by a plasma oxidation process at a temperature of about 25 to about 800° C. In some embodiments, the second sidewall oxide layer 44b is formed on the sidewall of the second gate conductive pattern 44a at a temperature of below about 400° C. When the second sidewall oxide layer 44b is formed at the temperature of below about 400° C., the underlying first semiconductor structure including the first gate structure 36 may not be thermally damaged.

As shown in the embodiments of FIG. 2I, a second gate spacer 44c is formed on the second sidewall oxide layer 44b. The second gate spacer 44c may be formed by processes substantially identical to those for forming the first gate spacer 34c. That is, after a second insulation layer is formed on the second gate oxide layer 42 to cover the second gate conductive pattern 44a, the second insulation layer may be partially etched to form the second gate spacer 44c on the second sidewall oxide layer 44b. As a result, a second gate structure 46 including the second gate oxide layer 42, the second gate conductive pattern 44a, the second sidewall oxide layer 44b and the second gate spacer 44c may be formed on the second substrate 40.

As described for various embodiments above, before the second gate spacer 44c is formed on the second sidewall oxide layer 44b, impurities may be implanted into portions of the semiconductor layer 40 adjacent to the second gate conductive pattern 44a by, for example, an ion implantation process, so that second source/drain regions (not shown) are formed at the portions of the second substrate 40.

In some embodiments, impurities may be implanted into portions of the second substrate 40 adjacent to the second gate conductive pattern 44a to form second preliminary source/drain regions 41 at the portions of the second substrate 40. Then, additional impurities may be implanted into the portions of the second substrate 40 where the second preliminary source/drain regions 41 are positioned to form second source/drain regions 41′ having lightly doped drain (LDD) structures. The second preliminary source/drain regions 41 have relatively shallow junction depths, whereas the second source/drain regions 41′ have relatively deep junction depths.

A second wiring structure (metal layer) may be formed over the second gate structure 46 using a conductive material, such as a metal, a metal nitride, doped polysilicon and/or the like. The second wiring structure may be electrically connected to the second gate structure 46. As a result, a second semiconductor structure including the second gate structure 46 and the second wiring structure may be formed on the second substrate 40.

When the second semiconductor structure is formed, the resulting semiconductor device includes vertically stacked semiconductor structures. In the processes used for forming the second semiconductor structure, processing conditions of the processes used for forming the second semiconductor structure may be properly adjusted to control or even prevent damage to the underlying first semiconductor structure. In particular embodiments, as the second semiconductor structure is formed at the temperature of about 25 to about 800° C., the thermal damage to the underlying first semiconductor structure may be effectively prevented.

FIG. 3 is a cross sectional view illustrating methods of manufacturing a semiconductor device having stacked semiconductor structures in accordance with further embodiments of the present invention. In FIG. 3, processes for forming a first gate oxide layer 32, a first gate structure 36, an interlayer insulating layer 38 and a semiconductor layer (second substrate) 40 may be substantially identical to those described with reference to FIGS. 2A to 2F. Therefore, such processes need not be further described herein.

Referring now to the embodiments of FIG. 3, a second gate oxide layer 45 is formed on the semiconductor layer 40. The second gate oxide layer 42 may be formed using a plasma oxidation process and/or a CVP process. In some embodiments, the second gate oxide layer 45 is formed by the plasma oxidation process at a temperature of about 25 to about 800° C. In further embodiments, the second gate oxide layer 45 is formed at a temperature of below about 400° C. The second gate oxide layer 45 is then nitrified by a plasma nitrification process at a temperature of below about 500° C. in some embodiments. In other embodiments, plasma nitrification is at a temperature of below about 400° C. As the second gate oxide layer 45 is formed at the temperature below about 400° C. in some embodiments, the first semiconductor structure including the first gate structure 36 may not be thermally damaged.

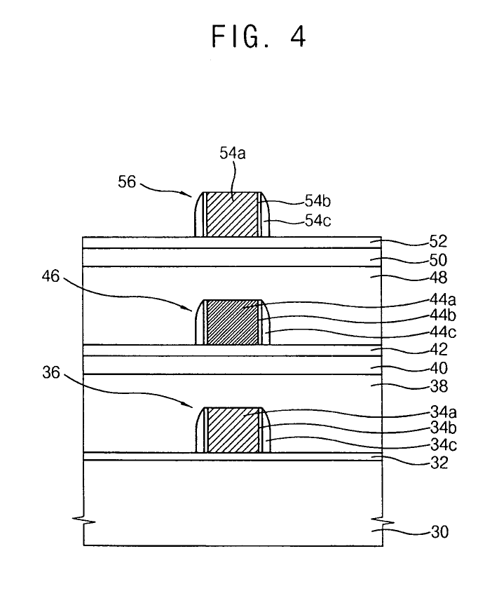

FIG. 4 is a cross sectional view illustrating methods of manufacturing a semiconductor device having stacked semiconductor structures in accordance with further embodiments of the present invention. In FIG. 4, processes for forming a first gate oxide layer 32, a first gate structure 36, a first interlayer insulating layer 38, a semiconductor layer (second substrate) 40, a second gate oxide layer 42 and a second gate structure 46 may be substantially identical to those described with reference to FIGS. 2A to 2I and need not be further described herein.

Referring to the embodiments of FIG. 4, a second interlayer insulating layer 48 is formed on the second gate oxide layer 42 to cover the second gate structure 46 including a second gate conductive pattern 44a, a second sidewall oxide layer 44b and a second gate spacer 44c. The second interlayer insulating layer 48 may be formed using an oxide substantially identical to that of the first interlayer insulating layer 38. The second interlayer insulating layer 48 may also be formed using an oxide different from that of the first interlayer insulating layer 38.

After a third substrate (semiconductor layer) 50 is formed on the second interlayer insulating layer 48, for example, using single crystalline silicon or polycrystalline silicon, a third gate oxide layer 52 is formed on the third substrate 50. The third gate oxide layer 52 may be formed by a plasma oxidation process at a temperature of about 25 to about 800° C. In some embodiments, the third gate oxide layer 52 is formed at a temperature of below about 400° C.

A third gate conductive pattern 54a is formed on the third gate oxide layer 52 by forming a third gate conductive layer on the third gate oxide layer 52 and partially etching the third gate conductive layer. A third sidewall oxide layer 54b and a third gate spacer 54c are successively formed on a sidewall of the third gate conductive pattern 54a to form a third gate structure 56 on the third gate oxide layer 52.

As described above with reference to other semiconductor layers, third source/drain regions may be formed at portions of the third substrate 50 adjacent to the third gate conductive pattern 54a by, for example, an ion implantation process. Alternatively, third source/drain regions having LDD structures may be formed at portions of the third substrate 50 adjacent to the third gate conductive pattern 54a as described above.

Additionally, a third wiring structure may be formed over the third gate structure 56 to form a third semiconductor structure on the third substrate 50. The formation of the third semiconductor structure completes formation of the semiconductor device having vertically stacked semiconductor structures for the embodiments illustrate in FIG. 4.

In some embodiments of the present invention, after a third interlayer insulating layer may be formed on the third substrate 50 to cover the third semiconductor structure. A fourth substrate and a fourth gate oxide layer may be formed on the third interlayer insulating layer. Then, a fourth semiconductor structure may be formed on the fourth gate oxide layer. Similarly, a fourth interlayer insulating layer through a K′th interlayer insulating layer (K′ being an integer equal to or greater than 5) may be successively formed on a fourth substrate to an L′th (L′ being an integer equal to or greater than 5) substrate, respectively. Here, a fifth gate oxide layer to an M′th (M′ is an integer equal to or greater than 6) gate oxide layer may be formed on the fifth substrate to the L′th substrate, respectively.

Additionally, a fifth semiconductor structure to an N′th (N′ is an integer equal to or greater than 6) semiconductor structure may be formed on the fifth gate oxide layer to the M′th gate oxide layer, respectively. The fourth to the M′th semiconductor structures may be substantially identical to the first to the third semiconductor structures described above.

According to some embodiments of the present invention, the semiconductor device has at least two vertically stacked semiconductor structures without any thermal or other damage to the semiconductor structures, which control of damage may be provided by controlling processing conditions in processes for forming the semiconductor structures. Therefore, the semiconductor structures may have good characteristics when the semiconductor device includes a plurality of vertically stacked semiconductor structures. The semiconductor device according to some embodiments of the present invention may include six vertically stacked semiconductor structures when the semiconductor device corresponds to a static random access memory (SRAM) device having six transistors.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A method of forming a semiconductor device having stacked structures, the method comprising:
forming a first semiconductor structure on a substrate;
forming a first interlayer insulating layer on the substrate, the first interlayer insulating layer having a substantially level upper face;
forming a semiconductor layer on the first interlayer insulating layer;
forming a first gate insulation layer on the semiconductor layer at a processing temperature selected to control a damage to the first semiconductor structure; and
forming a second semiconductor structure on the first gate insulation layer.

2. The method of claim 1, wherein forming a first gate insulation layer on the semiconductor layer at a processing temperature selected to control the damage to the first semiconductor structure comprises forming the first gate insulation layer at a temperature of about 25 to about 800° C.

3. The method of claim 1, wherein forming a first gate insulation layer on the semiconductor layer at a processing temperature selected to control the damage to the first semiconductor structure comprises forming the first gate insulation layer using a plasma oxidation process.

4. The method of claim 1, further comprising nitrifying the first gate insulation layer at a temperature of below about 500° C.

5. The method of claim 4, wherein nitrifying the first gate insulation layer comprise nitrifying the first gate insulation layer using a plasma nitrification process.

6. The method of claim 1, wherein the first semiconductor structure includes a first gate structure including a first gate conductive pattern and wherein the second semiconductor structure includes a second gate structure including a second gate conductive pattern and wherein the semiconductor layer includes silicon.

7. The method of claim 6, further comprising forming a first sidewall layer on a sidewall of the first gate conductive pattern.

8. The method of claim 7, further comprising forming a first gate spacer on the first sidewall layer.

9. The method of claim 8, further comprising forming a second sidewall layer on the second gate conductive pattern.

10. The method of claim 9, further comprising forming a second gate spacer on the second sidewall layer.

11. The method of claim 10, wherein forming a second sidewall layer comprises forming the second sidewall layer by an oxidation process at a temperature of about 25 to about 800° C.

12. The method of claim 6, further comprising successively forming interlayer insulating layers, semiconductor layers, gate insulation layers and semiconductor structures on the semiconductor device to provide a semiconductor device having at least three vertically stacked semiconductor structures formed at a processing temperature selected to control damage to underlying semiconductor structures while forming the successive gate insulation layers.

13. The method of claim 12, wherein the device comprises a static random access memory (SRAM) having six transistors and wherein successively forming comprises successively forming six vertically stacked semiconductor structures to form the six transistors.

14. The method of claim 1, further comprising successively forming interlayer insulating layers, semiconductor layers, gate insulation layers and semiconductor structures on the semiconductor device to provide a semiconductor device having at least three vertically stacked semiconductor structures formed at a processing temperature selected to control damage to underlying semiconductor structures while forming the successive gate insulation layers.

15. The method of claim 1, further comprising:
forming source/drain regions in the substrate proximate the first semiconductor structure; and
forming source/drain regions in the semiconductor layer proximate the second semiconductor structure.

16. A semiconductor device formed using the method of claim 1.

17. A semiconductor device formed using the method of claim 12.

18. The semiconductor device of claim 17, wherein the device comprises a static random access memory (SRAM) having six transistors and wherein the device includes six vertically stacked semiconductor structures that provide the six transistors.

19. A method of manufacturing a semiconductor device having stacked structures, comprising:
forming a first semiconductor structure on a first substrate, the first semiconductor structure including a first gate structure that has a first gate conductive pattern;
forming a first interlayer insulating layer on the first substrate, the first interlayer insulating layer having a level upper face;
forming a second substrate on the first interlayer insulating layer, the second substrate including silicon;
forming a first gate insulation layer on the second substrate without damaging the first semiconductor structure; and
forming a second semiconductor structure on the first gate insulation layer, the second semiconductor structure including a second gate structure that has a second gate conductive pattern.

20. The method of claim 19, wherein the first gate insulation layer is formed at a temperature of about 25 to about 800° C.

21. The method of claim 20, wherein the first gate insulation layer is formed by a plasma oxidation process.

22. The method of claim 19, further comprising nitrifying the first gate insulation layer at a temperature of below about 500° C.

23. The method of claim 22, wherein the first gate insulation layer is nitrified by a plasma nitrification process.

24. The method of claim 19, further comprising:
forming a second to a Kth (K is an integer greater than 2) interlayer insulating layers formed on the first gate insulation layer;
forming a third to an Lth (L is an integer greater than 3) substrates formed on the second to the Kth interlayer insulating layers, respectively;
forming a third to an Mth (M is an integer greater than 3) gate insulation layers formed on the third to the Lth substrates, respectively; and
forming a third to an Nth (N is an integer greater than 3) semiconductor structures formed on the third to the Mth gate insulation layers, respectively.
